(19) United States
(12) Patent Application Publication
(10) Pub. No.: US 2024/0030164 A1
(43) Pub. Date: Jan. 25, 2024

(54) SEMICONDUCTOR PACKAGE DEVICE AND METHOD OF MANUFACTURING SEMICONDUCTOR PACKAGE DEVICE

(71) Applicant: SHUNSIN TECHNOLOGY (ZHONG SHAN) LIMITED, Zhongshan (CN)

(72) Inventor: SHUN-HSING LIAO, Zhongshan City (CN)

(21) Appl. No.: 17/891,466

(22) Filed: Aug. 19, 2022

(30) Foreign Application Priority Data
Jul. 22, 2022 (CN) 202210869200.5

(51) Int. Cl. H01L 23/66; H01L 23/31; H01L 23/538; H01L 21/48; H01L 21/56

(52) U.S. Cl. CPC H01L 23/66; H01L 23/3128; H01L 23/5383; H01L 23/5386; H01L 21/4857; H01L 21/565; H01L 2223/6677; H01Q 1/2283

(57) ABSTRACT

A miniaturized semiconductor package device with enhanced functionality includes a redistribution layer, an electronic device, electronic components, a molding layer, an antenna element, and conductive terminals. The redistribution layer includes a first surface, a second surface opposite to the first surface, and a circuit layer. The electronic device and the electronic components are disposed on the first surface of the redistribution layer. The molding layer is formed on a first area of the first surface and covers the electronic device and the electronic components but does not cover a second area of the first surface. The antenna element is disposed on the second area of the first surface. The conductive terminals are disposed on the second surface of the redistribution layer and form electrical connections to the circuit layer.

### FIELD

The subject matter herein generally relates to chip manufacture, particularly to selectively forming molding layers in semiconductor package devices and methods of manufacturing the semiconductor package devices.

### BACKGROUND

Due to the demand for miniaturization of semiconductor devices, a reduced package size is required to meet the requirements for use. Therefore, there is a need not only for a miniaturized package structure, but also including more functions.

### BRIEF DESCRIPTION OF THE DRAWINGS

Many aspects of the present disclosure are better understood with reference to the following drawings. The components in the drawings are not necessarily drawn to scale, the emphasis instead being placed upon clearly illustrating the principles of the present disclosure. It will be appreciated that for simplicity and clarity of illustration, where appropriate, reference numerals have been repeated among the different figures to indicate corresponding or analogous elements.

FIG. 1 is a schematic cross-sectional diagram of a semiconductor package device according to an embodiment of the disclosure; and

FIGS. 2A, 2B, 2C, 2D, 2E, 2F, 2Q 2H, 2I, 2J, 2K and 2L are schematic cross-sectional diagrams illustrating a process flow of a method of manufacturing a semiconductor package device according to an embodiment of the disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one”.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series, and the like.

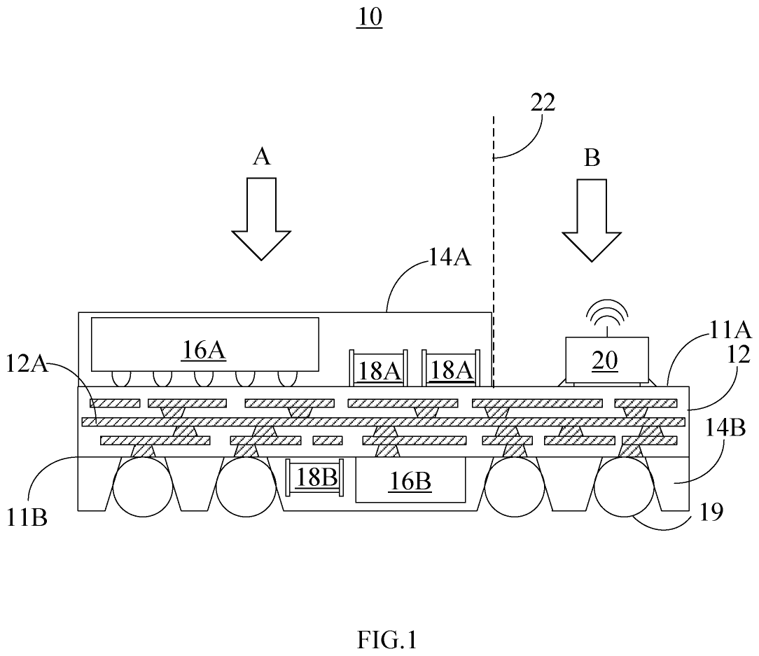

FIG. 1 illustrates a cross-sectional view of semiconductor package device 10 according to an embodiment of the disclosure. The semiconductor package device 10 comprises a redistribution layer 12, molding layers 14A and 14B, electronic devices 16A and 16B, electronic components 18A and 18B, conductive terminals 19, and an antenna element 20.

The redistribution layer 12 comprises a top surface (first surface) 11A, a bottom surface (second surface) 11B opposite to the top surface 11A, and a circuit layer 12A. According to an embodiment of the disclosure, the redistribution layer 12 can first be formed layer by layer on a carrier, then the carrier is removed after the formation of the redistributed layer 10 is completed. The formation of the redistribution layer 12 may involve multiple deposition or coating processes, patterning processes, and planarization processes. The deposition or coating processes can form insulating layers on the circuit layers 12A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed insulating layers and circuit layers 12A to facilitate subsequent processes. The planarization process may comprise a mechanical polishing process, a chemical mechanical polishing (CMP) process, or other applicable process and combinations thereof.

The redistribution layer 12 can also be formed by an additive buildup process. The additive buildup process may comprise the alternating stacking of one or more dielectric layers and conductive patterns or traces of the circuit layers 12A. The conductive patterns or traces fan out across the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 12 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

The bottom surface (second surface) 11B of the redistribution layer 12 has a molding layer 14B with a plurality of through holes passing through the molding layer 14B. The number of the conductive terminals 19 corresponds to the through holes of the molding layer 14B, and the conductive terminals 19 are respectively disposed in the through holes and electrically connected to the circuit layer 12A. The conductive terminals 19 can be disposed on the bottom surface 11B of the redistribution layer 12 by ball implantation. The semiconductor package device 10 according to an embodiment of the disclosure can be electrically connected to an external device (such as a printed circuit board) by these conductive terminals 19. The conductive terminals 19 may include conductive balls, conductive posts, conductive bumps, combinations thereof, or other forms and shapes formed by a ball-mounting process, an electroless plating process, or other suitable processes. According to the embodiments of the disclosure, a soldering process and a reflowing process can be performed to enhance adhesion between the conductive terminals 19 and the redistribution layer 12.

According to an embodiment of the disclosure, the material of the molding layer 14B can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

As shown in FIG. 1, an electronic device 16A and electronic components 18A are provided on the top surface (first surface) 11A of the redistribution layer 12, and an electronic device 16B and an electronic component 18B are provided on the bottom surface (second surface) 11B of the redistribution layer 12 between two conductive terminals 19. In FIG. 1, only the electronic devices 16A and 16B, and three electronic components 18A and 18B are shown. However, the actual number is not limited to these, and those with need can set a specific number of electronic devices 16A and 16B and electronic components 18A and 18B. The electronic devices 16A and 16B may be a semiconductor die, a semiconductor chip, or a package including a plurality of electronic devices. The electronic devices 16A and 16B may be connected to the circuit layer 12A of the redistribution layer 12 via conductive wires such as gold, copper, or aluminum wires. The electronic devices 16A and 16B may be optoelectronic devices, micro-electromechanical systems (MEMS), power amplifier chips, power management chips, biological identification devices, microfluidic systems, or a physical sensor that measures changes in heat, light levels, and pressure. The electronic devices 16A and 16B also can also comprise semiconductor chips such as imaging sensor devices, light-emitting diodes (LEDs), solar cells, accelerators, gyroscopes, fingerprint readers, micro actuators, surface acoustic wave devices, or process sensors or ink printer heads made by a wafer scale package (WSP) process. The electronic components 18A and 18B may be electrically connected to the circuit layer 12A of the redistribution layer 12. According to an embodiment of the disclosure, the electronic components 18A and 18B may be passive, such as a resistor, a capacitor, an inductor, a filter, an oscillator, and so on. In other embodiments, the electronic components 18A and 18B may also be an electronic terminal.

The electronic devices 16A and 16B and the electronic components 18A and 18B can be disposed on the redistribution layer 12 by a flip-chip packaging, and are electrically connected to the circuit layer 12A in the redistribution layer 12. In addition, the electronic devices 16A and 16B and the electronic components 18A and 18B can also be disposed on the redistribution layer 12 through an adhesive layer, and electrically connected to the circuit layer 12A in the redistribution layer 12 by wire bonding.

According to an embodiment of the disclosure, the adhesive layer can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

The molding layer 14A is formed on the redistribution layer 12 and covers the electronic device 16A and the electronic components 18A. According to the embodiment of the disclosure, the molding layer 14A is not formed on the entirety of the top surface (the first surface) 11A of the redistribution layer 12. The molding layer 14A is only formed on the area A of the top surface 11A of the redistribution layer 12, and does not cover the area B of the top surface 11A of the redistribution layer 12. Specifically, the molding layer 14A is absent from the area B of the top surface 11A of the redistribution layer 12.

The area A and the area B are bounded by the boundary line 22. According to an embodiment of the disclosure, the material of the molding layer 14A can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

The antenna element 20 is disposed on the area B of the top surface 11A of the redistribution layer 12. The types of antenna element 20 may include loop antennas, broadband dipoles, monopole antennas, folded dipole antennas, microstrip or patch antennas, planar inverted-F antennas (PIFA), inverted-F antennas (IFA), tapered slot antennas (TSA), slotted waveguide antennas, half-wave and quarter-wave antennas, etc. The antenna element 20 can be connected with die attach pads, lead fingers, tie rods, and additional conductive elements to form antenna elements for applications including wireless handheld devices that require transmitting and receiving RF signals, such as smart phones, two-way communication devices, personal computers, tablet computers, RF tags, sensors, BLUETOOTH and WI-FI devices, Internet of Things (IOT), home protection devices, and remote control devices, etc.

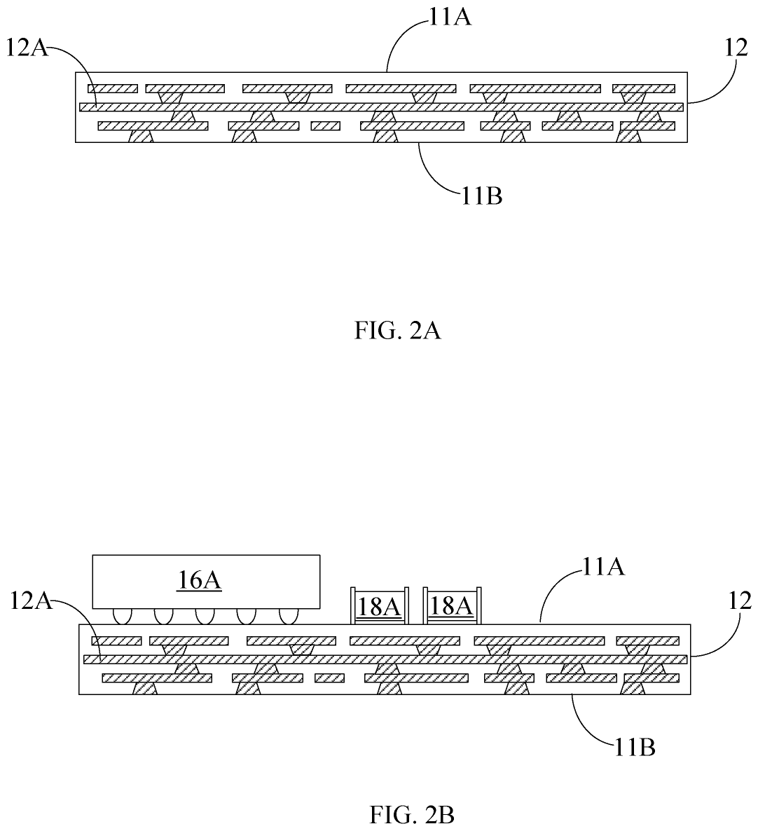

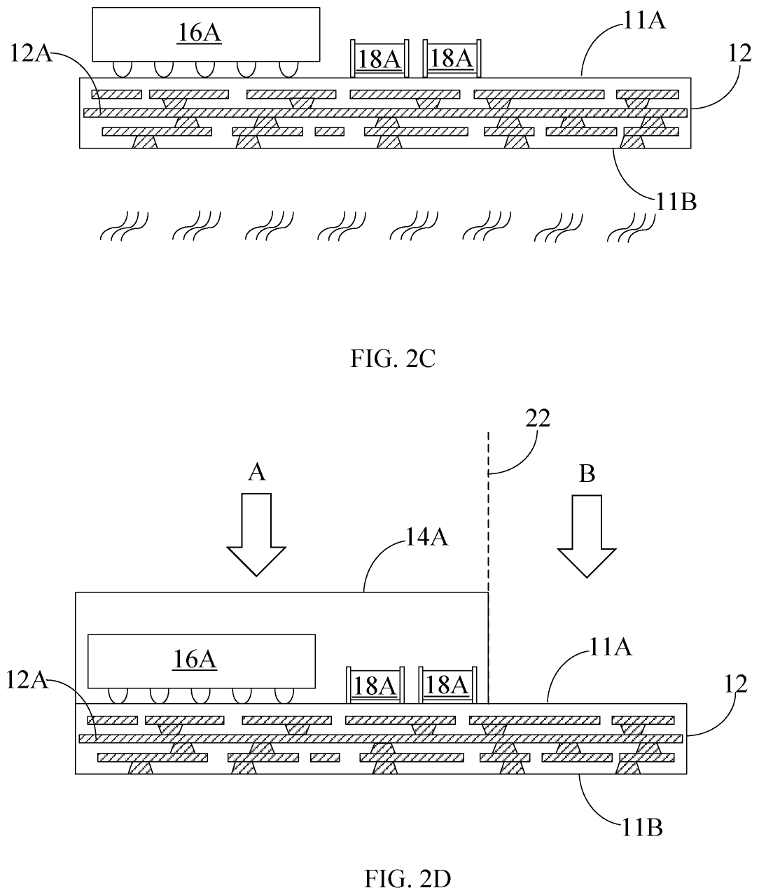

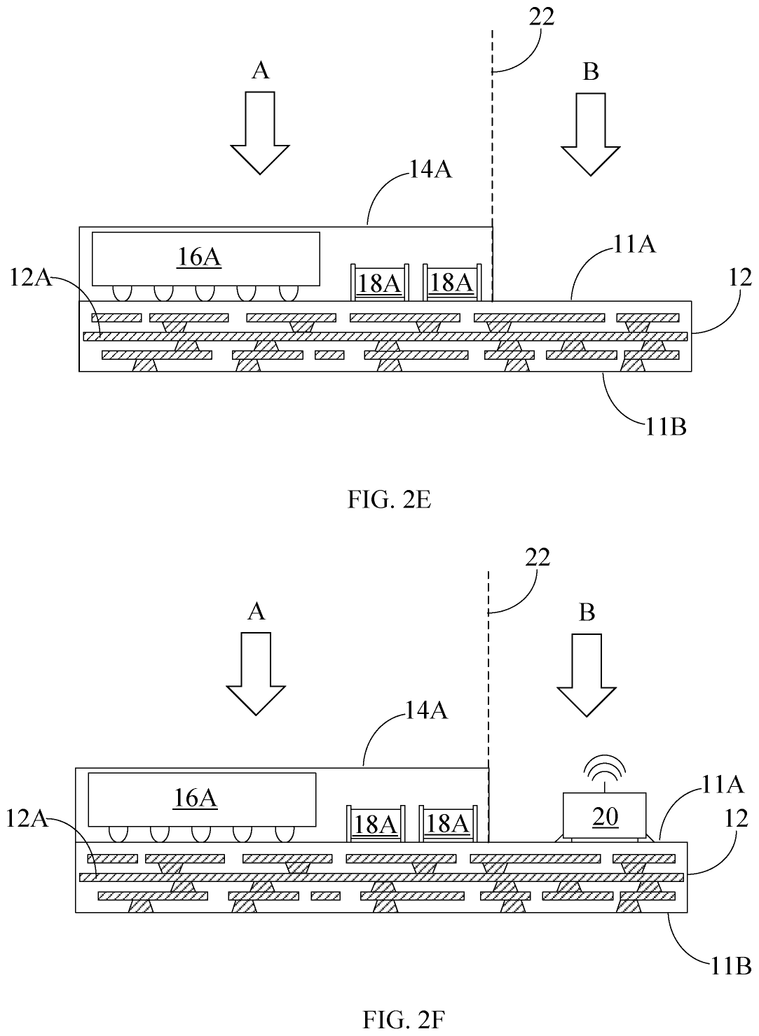

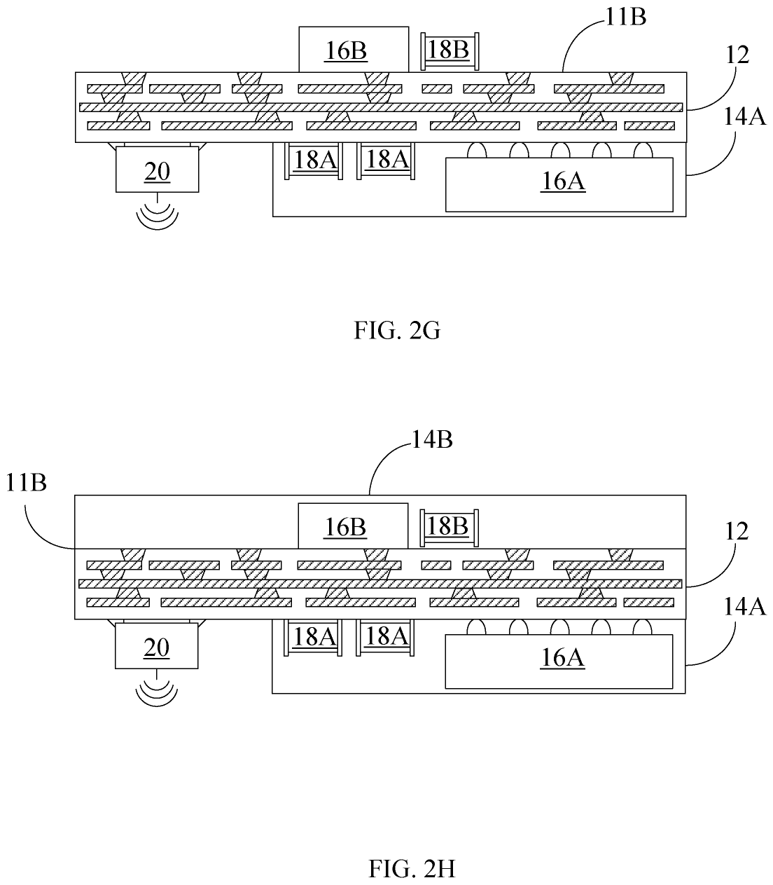

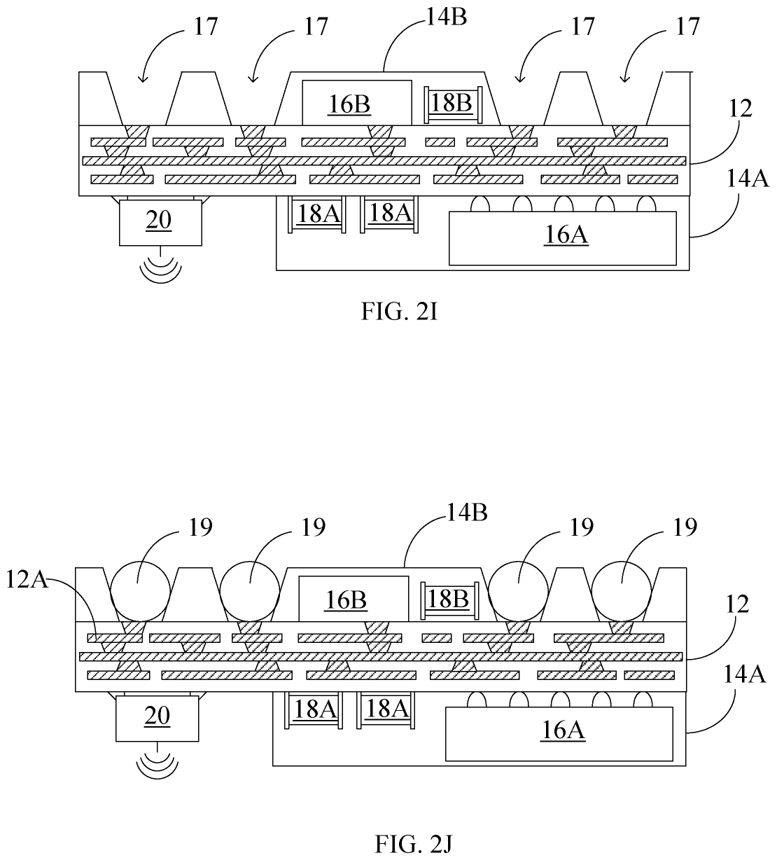

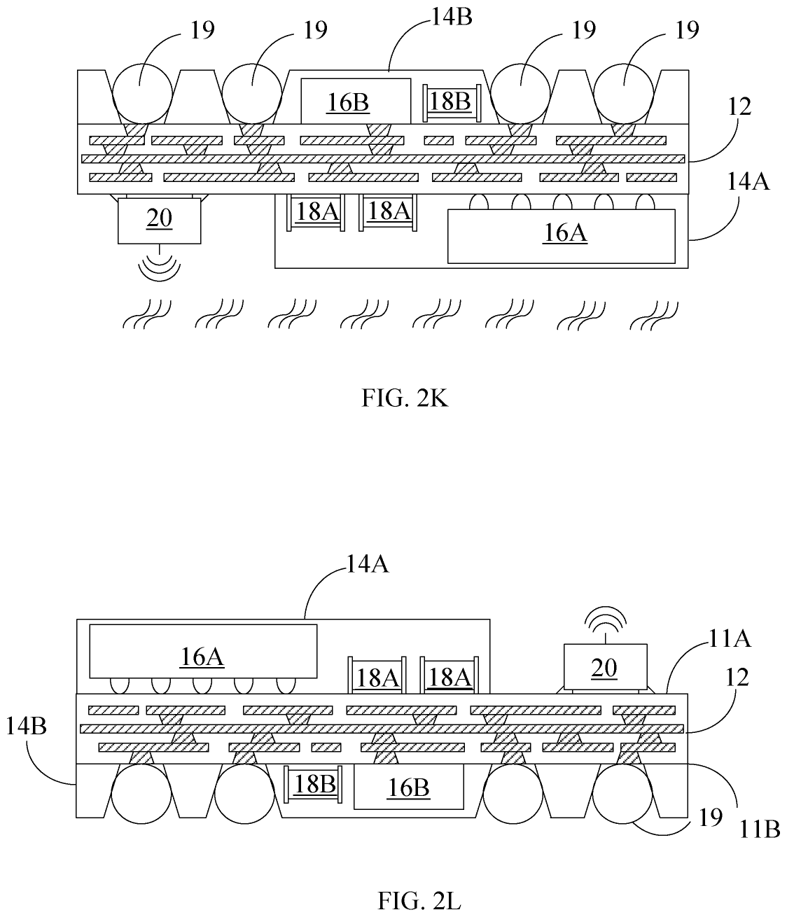

FIGS. 2A-2L illustrate other embodiments for implementation of the method of the disclosure. In FIG. 2A, redistribution layer 12 is provided. The redistribution layer 12 has a top surface 11A, a bottom surface 11B on the opposite side of the top surface 11A, and a circuit layer 12A. According to an embodiment of the disclosure, the redistribution layer 12 can first be formed layer by layer on a carrier, then the carrier is removed after the formation of the redistributed layer 10 is completed. The formation of the redistribution layer 12 may involve multiple deposition or coating processes, patterning processes, and planarization processes. The deposition or coating processes can form insulating layers or the circuit layers 12A. The deposition or coating processes may comprise a spin coating process, an electroplating process, an electroless process, a chemical vapor deposition (CVD) process, a physical vapor deposition (PVD) process, an atomic layer deposition (ALD) process, and other applicable processes and combinations thereof. The patterning process can be used to pattern the formed insulating layers and circuit layers 12A. The patterning process may comprise a photolithography process, an energy beam drilling process (for example, a laser beam drilling process, an ion beam drilling process, or an electron beam drilling process), an etching process, a mechanical drilling process, or other applicable processes and combinations. The planarization process can be used to provide a flat top surface for the formed insulating layers and circuit layers 12A to facilitate subsequent processes. The planarization process may comprise a mechanical polishing process, a chemical mechanical polishing (CMP) process, or other applicable processes and combinations thereof.

The redistribution layer 12 can also be formed by an additive buildup process. The additive buildup process may comprise the alternating stacking of one or more dielectric layers and conductive patterns or traces of the circuit layers 12A. The conductive patterns or traces fan out across the occupied space of the electronic device, or are in a fan-shaped layout allowing the electrical traces into the occupied space of the electronic device. The conductive patterns can be formed by a plating process such as an electroplating process or an electroless plating process. The conductive pattern may comprise a conductive material, such as copper or other plateable metals. The dielectric layer of the redistribution layer 12 can be made of a photo-definable organic dielectric such as polyimide (PI), benzocyclobutene (BCB), or polybenzoxazole (PBO). In other embodiments, the dielectric material of the redistribution layer 12 may also be an inorganic dielectric layer. The inorganic dielectric layer may comprise silicon nitride (Si₃N₄), silicon oxide (SiO₂), or SiON. The inorganic dielectric layer can be formed by growing an inorganic dielectric layer using an oxidation or nitridation process.

As FIG. 2B shows, the electronic device 16A and the electronic components 18A are provided on the top surface 11A of the redistribution layer 12. In FIG. 2B, only a single electronic device 16A and two electronic components 18A are shown. However, the actual number is not limited to these, and those with need can set a specific number of electronic device 16A and electronic component 18A.

The electronic device 16A may be a semiconductor die, a semiconductor chip, or a package including a plurality of electronic devices. The electronic device 16A may be connected to the circuit layer 12A of the redistribution layer 12 via conductive wires such as gold wires, copper wires, or aluminum wires. The electronic device 16A may be optoelectronic devices, micro-electromechanical systems (MEMS), power amplifier chips, power management chips, biological identification devices, microfluidic systems, or a physical sensor measuring changes in physical quantities such as heat, light, and pressure. The electronic device 16A also can also comprise semiconductor chips such as imaging sensor devices, light-emitting diodes (LEDs), solar cells, accelerators, gyroscopes, fingerprint readers, micro actuators, surface acoustic wave devices, or process sensors or ink printer heads made by a wafer scale package (WSP) process. The electronic component 18A may be electrically connected to the circuit layer 12A of the redistribution layer 12. According to an embodiment of the disclosure, the electronic component 18A may be a passive component, such as a resistor, a capacitor, an inductor, a filter, an oscillator, and so on. In other embodiments, the electronic component 18A may also be an electronic terminal.

The electronic device 16A and the electronic components 18A can be disposed on the redistribution layer 12 by a flip-chip packaging, and are electrically connected to the circuit layer 12A in the redistribution layer 12. In addition, the electronic device 16A and the electronic components 18A can also be disposed on the redistribution layer 12 through an adhesive layer, and electrically connected to the circuit layer 12A in the redistribution layer 12 by wire bonding.

According to an embodiment of the disclosure, the adhesive layer can be formed of various materials, including a polyimide (PI), polyethylene terephthalate (PET), Teflon, liquid crystal polymer (LCP), polyethylene (PE), polypropylene (PP), polystyrene (PS), polyvinyl chloride (PVC), nylon or polyamides, polymethylmethacrylate (PMMA), acrylonitrile-butadiene-styrene, phenolic resins, epoxy resin, polyester, silicone, polyurethane (PU), polyamide-imide (PAI) or a combination thereof, not being limited thereto, as long as such materials have the required adhesive properties.

In FIG. 2C, the semi-finished product is baked to cure the adhesive between the electronic device 16A and the redistribution layer 12, and between the electronic component 18A and the redistribution layer 12 to fix the electronic device 16A and the electronic components 18A on the redistribution layer 12. Next, in FIG. 2D, the molding layer 14A is formed on the redistribution layer 12 and covers the electronic device 16A and the electronic components 18A. According to the embodiment of the disclosure, the molding layer 14A is not formed on the entire top surface 11A of the redistribution layer 12. The molding layer 14A only formed on the area A of the top surface 11A of the redistribution layer 12, and not on the area B of the top surface 11A of the redistribution layer 12. The area A and the area B are bounded by the boundary line 22. According to an embodiment of the disclosure, the material of the molding layer 14A can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material. Next, in FIG. 2E, the molding layer 14A is then polished by a planarization process to decrease the thickness of the molding layer 14A. According to the embodiment of the disclosure, the planarization process may comprise a mechanical polishing process, a chemical mechanical polishing (CMP) process, or other applicable process and combinations thereof.

In FIG. 2F, the antenna element 20 is disposed on the area B of the top surface 11A of the redistribution layer 12. The types of antenna element 20 may include loop antennas, broadband dipoles, monopole antennas, folded dipole antennas, microstrip or patch antennas, planar inverted-F antennas (PIFA), inverted-F antennas (IFA), tapered slot antennas (TSA), slotted waveguide antennas, half-wave and quarter-wave antennas, etc. The antenna element 20 can be connected with die attach pads, lead fingers, tie rods, and additional conductive elements to form antenna elements for applications including wireless handheld devices that require transmitting and receiving RF signals, such as smart phones, two-way communication devices, personal computers, tablet computers, RF tags, sensors, BLUETOOTH and WI-FI devices, Internet of Things (JOT), home protection devices, and remote control devices, etc.

In FIG. 2G the semi-finished product is flipped so that the bottom surface 11B of the redistribution layer 12 faces upwards. Next, the electronic device 16B and the electronic component 18B are provided on the bottom surface 11B of the redistribution layer 12. In FIG. 2G only an electronic device 16B and electronic components 18B are shown. However, the actual number is not limited to these, and those with need can set a specific number of electronic devices 16B and electronic components 18B. Regarding the types and installation methods of the electronic device 16B and the electronic component 18B, reference may be made to those of the electronic devices 16A and the electronic components 18A, and details are not repeated here to simplify the description.

Next, in FIG. 2H, the molding layer 14B is formed on the bottom surface 11B of the redistribution layer 12 and covers the electronic device 16B and the electronic component 18B. According to an embodiment of the disclosure, the material of the molding layer 14B can be epoxy resin, cyanate resin, bismaleimide triazine, glass fiber, polybenzoxazole, polyimide, nitride (for example, silicon nitride), oxide (for example, silicon oxide), silicon oxynitride, or similar insulating materials, insulating organic material mixed with epoxy resin and glass fiber, or ceramic material.

In FIG. 2I, portions of the molding layer 14B are removed to form the through holes 17. According to embodiments of the disclosure, the through holes 17 may be formed using mechanical drilling, etching, or laser drilling. Next, in FIG. 2J, the conductive terminals 19 are placed into the through holes 17 and connected to the circuit layer 12A. The semiconductor package device according to an embodiment of the disclosure can be electrically connected to an external device (such as a printed circuit board) by these conductive terminals 19. The conductive terminals 19 may include conductive balls, conductive posts, conductive bumps, combinations thereof, or other forms and shapes formed by a ball-mounting process, an electroless plating process, or other suitable processes.

In FIG. 2K, a soldering process and a reflowing process can be performed to enhance the adhesion between the conductive terminals 19 and the redistribution layer 12. Next, in FIG. 2L, the semi-finished product is turned over so that the top surface 11A of the redistribution layer 12 faces upward, and the semiconductor packaging device according to an embodiment of the disclosure is completed.

According to the embodiments of the disclosure, the molding layer is selectively formed on a part of the redistribution layer, and the area of the circuit redistribution layer not covered by the molding layer can be used to install antenna elements or other devices with heat dissipation requirements, effectively improving the integration density of the semiconductor packaging device and achieving the purpose of miniaturizing the semiconductor packaging device.

Many details are often found in the relevant art and many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A semiconductor package device comprising:
a redistribution layer comprising a first surface, a second surface opposite to the first surface, and a circuit layer;
a first electronic device and a first electronic component disposed on the first surface of the redistribution layer;
a first molding layer formed on a first area of the first surface and covering the first electronic device and the first electronic component, without covering a second area of the first surface;
an antenna element disposed on the second area of the first surface; and
a plurality of conductive terminals disposed on the second surface of the redistribution layer and electrically connected to the circuit layer.

2. The semiconductor package device of claim 1, further comprising a second electronic device and a second electronic component disposed on the second surface of the redistribution layer.

3. The semiconductor package device of claim 2, wherein the second electronic device and the second electronic component are disposed between two of the conductive terminals.

4. The semiconductor package device of claim 3, further comprising a second molding layer formed on the second surface and covering the second electronic device and the second electronic component.

5. A semiconductor package device comprising:
a redistribution layer comprising a first surface, a second surface opposite to the first surface, and a circuit layer;
a first electronic device and a first electronic component disposed on the first surface of the redistribution layer;
a first molding layer formed on a first area of the first surface and covering the first electronic device and the first electronic component, without covering a second area of the first surface;
a second electronic device and a second electronic component disposed on the second surface of the redistribution layer; and
an antenna element disposed on the second area of the first surface.

6. The semiconductor package device of claim 5, further comprising a second molding layer formed on the second surface and covering the second electronic device and the second electronic component.

7. The semiconductor package device of claim 6, further comprising a plurality of conductive terminals disposed on the second molding layer and electrically connected to the circuit layer.

8. The semiconductor package device of claim 7, wherein the second electronic device and the second electronic component are disposed between two of the conductive terminals.

9. A method of manufacturing a semiconductor package device, the method comprising:
providing a redistribution layer comprising a first surface, a second surface opposite to the first surface, and a circuit layer;
disposing a first electronic device and a first electronic component on the first surface of the redistribution layer;
forming a first molding layer on a first area of the first surface and covering the first electronic device and the first electronic component, without covering a second area of the first surface;
disposing an antenna element on the second area of the first surface; and
disposing a plurality of conductive terminals on the second surface of the redistribution layer and electrically connected to the circuit layer.

10. The method of claim 9, further comprising disposing a second electronic device and a second electronic component on the second surface of the redistribution layer.

11. The method of claim 10, wherein the second electronic device and the second electronic component are disposed between two of the conductive terminals.

12. The method of claim 10, further comprising forming a second molding layer on the second surface and covering the second electronic device and the second electronic component.

13. The method of claim 12, further comprising forming a plurality of through holes on the second molding layer for disposing the conductive terminals.

14. The method of claim 13, wherein the through holes are formed by mechanical drilling, etching or laser drilling.
